(19) United States
(12) Patent Application Publication
(10) Pub. No.: US 2002/0177329 A1
(43) Pub. Date: Nov. 28, 2002

(54) Surface densification of low dielectric constant film

(76) Inventors: Neng-Hui Yang, Hsinchu (TW); Ming-Sheng Yang, Hsinchu (TW)

Correspondence Address: J.C. Patents, Inc., 1340 Reynolds Ave., Suite 114, Irvine, CA, 92614, US

(21) Appl. No.: 09/829,220

(22) Filed: Apr. 9, 2001

(30) Foreign Application Priority Data
Apr. 2, 2001 (TW) 90107849

(51) Int. Cl. H01L 21/26; H01L 21/324; H01L 21/42; H01L 21/477; H01L 21/31; H01L 21/469

(52) U.S. Cl. 438/798; 438/765; 438/769; 438/783

(57) ABSTRACT

A method of densifying a superficial layer on a low dielectric constant film. A substrate is provided. A low dielectric constant material layer is formed over the substrate. An inert gas plasma treatment of the low dielectric constant material layer is conducted so that a superficial layer of the low dielectric constant material layer is densified into a protective layer. The protective layer protects the low dielectric constant material layer against attacks by plasma and chemicals during subsequent processes and prevents any deterioration of electrical properties.

### CROSS-REFERENCE TO RELATED APPLICATION

This application claims the priority benefit of Taiwan application serial no. 90107849, filed Apr. 2, 2001.

### BACKGROUND OF THE INVENTION

1. Field of Invention

The present invention relates to a method of forming multi-level interconnects. More particularly, the present invention relates to a method of densifying a superficial layer of a low dielectric film.

2. Description of Related Art

Copper is now frequently used in the fabrication of semiconductor devices. Copper has low electrical resistance and is resistant to electromigration. Moreover, copper may be deposited by electroplating or chemical vapor deposition. Hence, copper is a commonly used material for fabricating interconnects. Because copper is difficult to etch, a damascene process is employed for producing copper lines in an integrated circuit.

However, as size of devices continue to shrink due to the fabrication of ultra-large-scale integration (ULSI) chip, resistor-capacitor delay (RC) between multi-level interconnects limits the ultimate operating speed of the devices. To reduce RC delay as much as possible, low dielectric constant material is now routinely used as a medium for insulating various multi-level interconnects.

In general, conventional low dielectric constant film has a relatively low density and a rather loose structure. Therefore, maintaining a low dielectric constant for the dielectric film is difficult. The low dielectric constant film is particularly vulnerable to damages caused by plasma treatment and solution treatment. However, plasma treatment (for example, etching, photoresist removal) and solution treatment are indispensable processes in semiconductor manufacturing. When a low dielectric constant film layer is damaged by plasma treatment or solution treatment, there will be a drop in breakdown voltage, a production of leakage current and a rise in the value of dielectric constant. In other words, a damaged dielectric film always shows some deterioration of electrical properties. Ultimately, integrity of the associated device is compromised.

### SUMMARY OF THE INVENTION

Accordingly, one object of the present invention is to provide a method of densifying a low dielectric constant film and forming a protective layer so that surface resistance of the low dielectric constant film is strengthened.

A second object of this invention is to provide a method of densifying a low dielectric constant film capable of protecting the low dielectric constant film against plasma or chemical attack so that desired electrical properties can be maintained.

To achieve these and other advantages and in accordance with the purpose of the invention, as embodied and broadly described herein, the invention provides a method of densifying a low dielectric constant film. First, a substrate having a conductive region thereon is provided. A cap layer, a first dielectric layer, an etching stop layer and a second dielectric layer are sequentially formed over the substrate. The substrate is placed inside a plasma-enhanced chemical vapor deposition (PECVD) station. A dual damascene structure is formed in the first and the second dielectric layer. After forming the dual damascene structure inside the PECVD station, an inert gas plasma treatment of the second dielectric layer is carried out so that a superficial protective layer is formed on the second dielectric layer. The protective layer protects the second dielectric layer against any form of destructive attack by plasma or chemicals in subsequent processes. Finally, a hydrogen plasma treatment of the substrate is conducted to remove any metal oxide on the dual damascene structure.

This invention also provides an alternative method of densifying a low dielectric film. First, a substrate is provided. A dielectric layer is formed over the substrate inside a plasma-enhanced chemical vapor deposition (PECVD) station. An inert gas plasma treatment of the dielectric layer is conducted to form a superficial protective layer on the dielectric layer. The protective dielectric layer protects the dielectric layer against any form of destructive attacks by plasma or chemicals in subsequent processes. Thereafter, a patterned photoresist layer is formed over the substrate. Using the photoresist layer as a mask, a portion of the dielectric layer is removed to form an opening. Finally, an oxygen plasma treatment of the substrate is carried out to remove the photoresist layer.

One major aspect of this invention is the inert gas plasma treatment of the low dielectric constant film so that a superficial layer of the low dielectric constant film is densified forming a protective layer. The protective layer thus formed protects the low dielectric film against chemical and plasma attacks in subsequent processing steps. Hence, deterioration of electrical properties of the low dielectric constant film is prevented.

In addition, the inert gas plasma used by the inert gas plasma treatment is supplied by the PECVD station for forming the low dielectric constant film. In other words, there is no need to purchase new equipment for performing the inert gas plasma treatment. Moreover, in another embodiment of this invention, the inert gas plasma treatment can also be carried out in the same station for forming a dielectric layer over the substrate. Since the treatment is compatible with other processes, processing flow is greatly simplified.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1E are schematic cross-sectional views showing the progression of steps for densifying a low dielectric constant film according to a first embodiment of this invention; and

FIGS. 2A through 2D are schematic cross-sectional views showing the progression of steps for densifying a low dielectric constant film according to a second embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

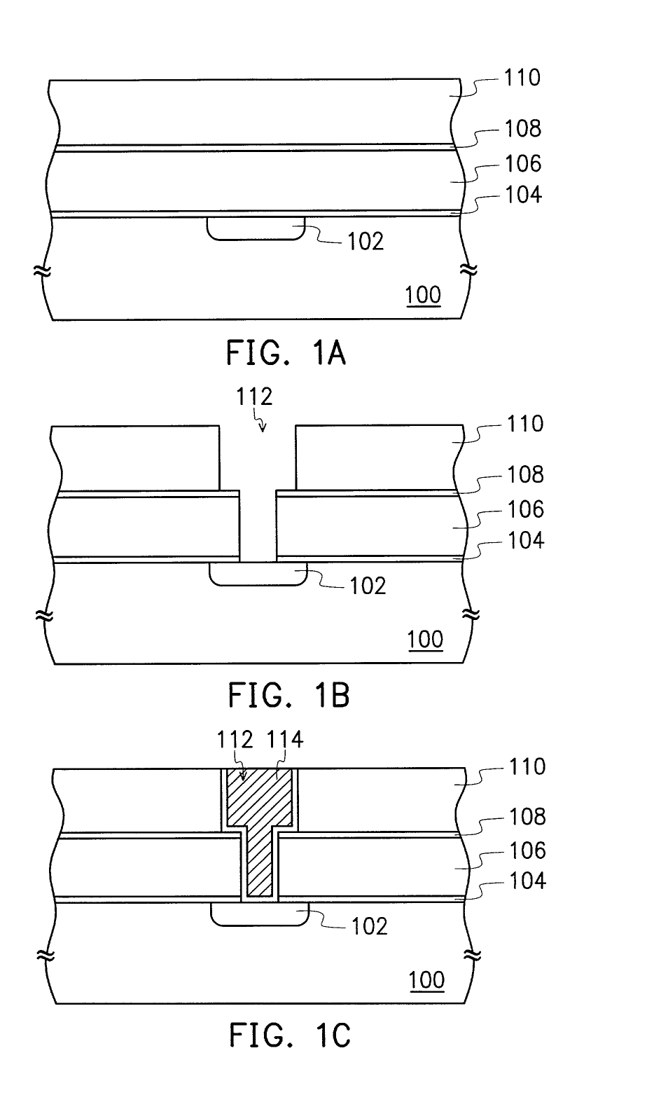

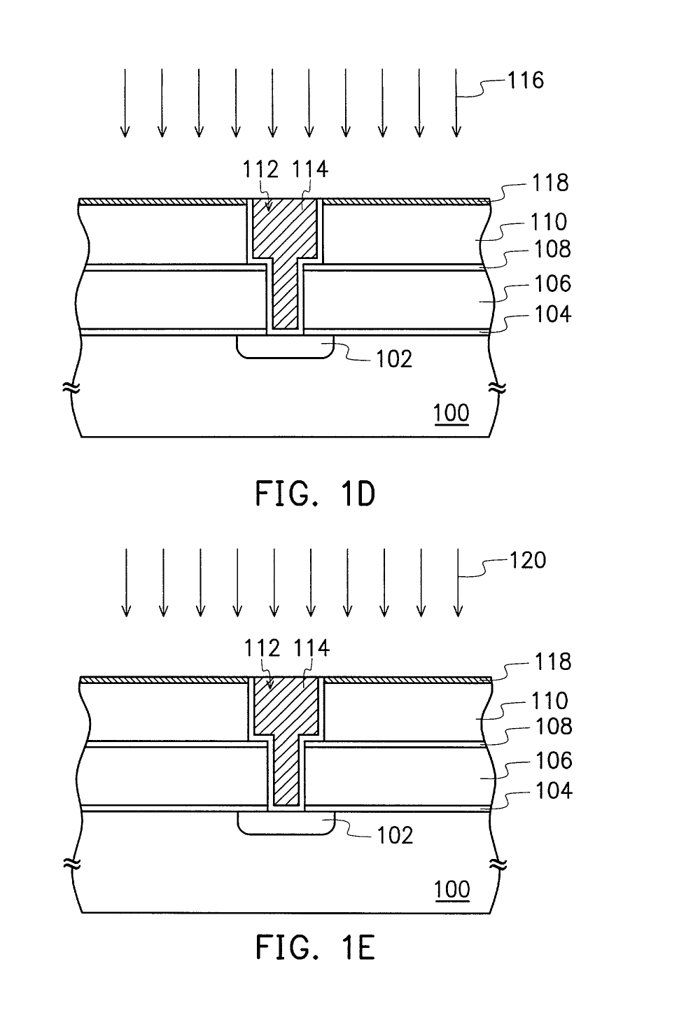

FIGS. 1A through 1E are schematic cross-sectional views showing the progress ion of steps for densifying a low dielectric constant film according to a first embodiment of this invention.

As shown in FIG. 1A, a substrate 100 having a conductive region 102 is provided. A cap layer 104 is formed over the substrate 100 and then a first dielectric layer 106 is formed over the cap layer 104. An etching stop layer 108 is formed over the first dielectric layer 106 and then a second dielectric layer 110 is formed over the etching stop layer 108. The cap layer 104 and the etching stop layer 108 can be a silicon nitride layer, a silicon oxide layer or a silicon carbide layer formed, for example, by chemical vapor deposition (CVD). The first dielectric layer 106 and the second dielectric layer 110 can be an organosilicate glass (OSG) layer formed, for example, by plasma-enhanced chemical vapor deposition (PECVD).

As shown in FIG. 1B, an opening 112 is formed in the first dielectric layer 106 and the second dielectric layer 110. The opening 112 can be a dual damascene opening, a damascene opening, a contact opening or a via opening. In this embodiment, a dual damascene opening is shown. The dual damascene opening 112 is formed, for example, by forming a photoresist layer (not shown) over the substrate 100 and then patterning out a conductive line trench in the second dielectric layer 110 by performing photolithographic and etching processes. After removing the photoresist layer, another photoresist layer (not shown) is formed over the substrate 100. Photolithographic and etching processes are again conducted to form a via opening in the first dielectric layer 106. The conductive line trench and the via opening together form a complete dual damascene opening 112.

As shown in FIG. 1C, a dual damascene structure 114 is formed inside the opening 112. For example, a conformal barrier layer (not shown) such as a tantalum layer, a tantalum nitride layer or a tungsten nitride layer is formed over the substrate 100. A metallic layer (not shown) is formed over the barrier layer, completely filling the opening 120. Finally, a chemical-mechanical polishing of the metallic layer is conducted to remove excess metal outside the opening 112 while using the barrier layer as an etching stop layer.

As shown in FIG. 1D, an inert gas plasma treatment 116 of the second dielectric layer 110 is carried out to form a protective layer 118 over the second dielectric layer 110. The superficial protective layer 118 protects the second dielectric layer 110 against any possible attack by plasma or chemical in subsequent processes. The protective layer 118 preferably has a thickness between about 30 Å and 100 Å. Gases used in the inert gas plasma treatment 116 may be selected from a group consisting of nitrogen, helium and argon. In addition, the inert gas plasma can be produced by the same plasma-enhanced chemical vapor deposition (PECVD) station for forming the first dielectric layer 106 and the second dielectric layer 110. To perform the inert gas plasma treatment, pressure inside the PECVD station is set between about 0.1 and 10 torrs, power produced by the PECVD station is set between about 0.5 and 10 W/cm² and operating temperature is set between about 250° C. and 450° C.

As shown in FIG. 1E, a plasma treatment 120 of the substrate 100 is carried out to remove metallic oxide material on the surface of the dual damascene structure 114. Ammonia or hydrogen is used as a source of gas for conducting the plasma treatment 120.

Because the hydrogen or ammonia plasma treatment 120 is conducted after the inert gas plasma treatment 116, the protective layer 118 on the second dielectric layer 110 is able to prevent any attack by the hydrogen or ammonia plasma. Hence, deterioration of electrical properties of the second dielectric layer 110 is minimized. In addition, the inert gas plasma treatment 116 has minimal effect on copper material.

Furthermore, the inert gas plasma required by the inert gas plasma treatment 116 can be produced by the PECVD station used for forming the first dielectric layer 106 and the second dielectric layer 110. In other words, the inert gas plasma treatment is compatible with conventional manufacturing step and there is no need to purchase new equipment.

Table 1 lists some test parameters showing the difference in properties for a dielectric constant film with or without a helium plasma treatment.

TABLE 1
Test results of a low dielectric constant film with or without
helium plasma treatment

| | | | | Ammonia |
|---|---|---|---|---|
| | Post- | | | Treatment After |
| Surface | Deposition | Ammonia | Helium | Helium |
| Treatment | (untreated) | Treatment | Treatment | Treatment |
| Dielectric | 2.72 | 2.84 | 2.75 | 2.73 |
| Constant | | | | |
| Breakdown | 6.1 | 5.27 | 6 | 5.96 |
| Voltage | | | | |
| (MV/cm) | | | | |
| Thickness loss | 0 | 35 | <10 | <15 |
| (Å) | | | | |

Before any treatment of the low dielectric constant film (organosilicate) treatment, the film has a dielectric constant of about 2.72, a breakdown voltage of about 6.1 MV/cm and a film loss of 0 Å (as shown in column 2 of Table 1). After an ammonia plasma treatment, the dielectric constant increases to about 2.84, the breakdown voltage drops to about 5.27 MV/cm and the film loss is about 35 Å (as shown in column 3 of Table 1). Therefore, electrical properties of the low dielectric constant deteriorate after an ammonia plasma treatment.

After a helium plasma treatment, the dielectric constant increases to about 2.75, the breakdown voltage drops to about 6 MV/cm and the film loss is less than about 10 Å (as shown in column 4 of Table 1). Hence, helium plasma treatment has a minor effect on the electrical properties of the low dielectric constant film.

If the ammonia plasma treatment is conducted after the helium plasma treatment, the dielectric constant increases slightly to about 2.73, the breakdown voltage drops to about 5.96 MV/cm and the film loss is less than 15 Å (as shown in column 5 of Table 1). Thus, the ammonia plasma treatment affects the properties of the low dielectric constant film only lightly. In other words, the inert gas plasma treatment is able to protect the low dielectric constant film against subsequent plasma treatment.

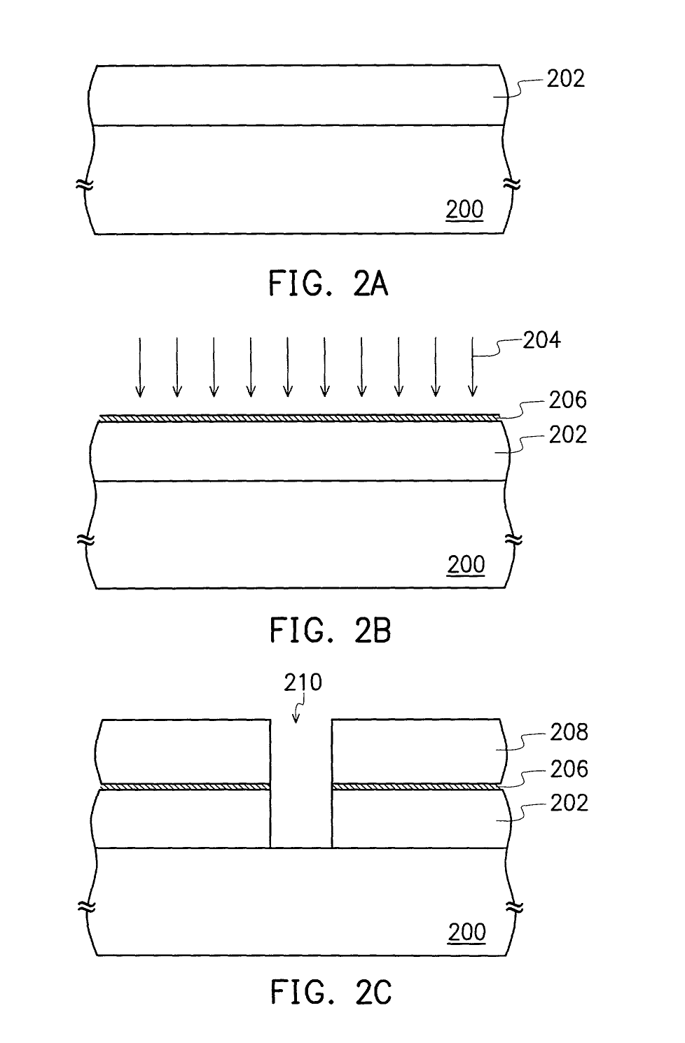

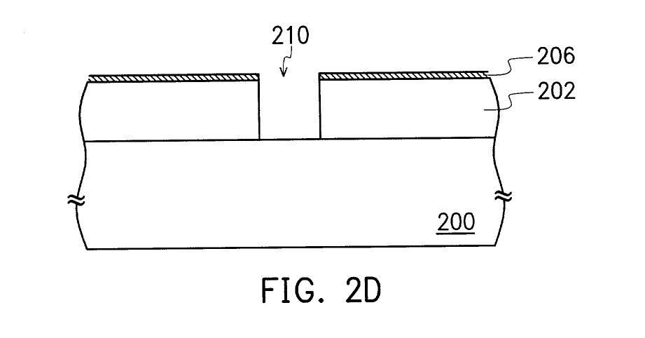

FIGS. 2A through 2D are schematic cross-sectional views showing the progression of steps for densifying a low dielectric constant film according to a second embodiment of this invention. In the second embodiment, how an inert plasma treatment before oxygen plasma ashing protects the low dielectric constant film is illustrated.

As shown in FIG. 2A, a substrate 200 is provided. A dielectric layer 202 is formed over the substrate 200. The dielectric layer 202 can be an organosilicate layer formed, for example, by plasma-enhanced chemical vapor deposition (PECVD).

As shown in FIG. 2B, an inert gas plasma treatment 204 of the dielectric layer 202 is carried out to form a protective layer 206 over the dielectric layer 202. The superficial protective layer 206 protects the dielectric layer 202 against any possible attack by plasma or chemical in subsequent processes. The protective layer 206 preferably has a thickness between about 30 Å and 100 Å. Gases used in the inert gas plasma treatment 204 may be selected from a group consisting of nitrogen, helium and argon. In addition, the inert gas plasma can be produced by the same plasma-enhanced chemical vapor deposition (PECVD) station for forming the dielectric layer 202. To perform the inert gas plasma treatment, pressure inside the PECVD station is set between about 0.1 and 10 torrs, power produced by the PECVD station is set between about 0.5 and 10 W/cm² and operating temperature is set between about 250° C. and 450° C.

As shown in FIG. 2C, a patterned photoresist layer 208 is formed over the substrate 200. An opening 210 is formed in the dielectric layer 202. The opening 210 is formed, for example, by performing an anisotropic etching to remove a portion of the dielectric layer 202 using the photoresist layer 208 as a mask.

As shown in FIG. 2D, a plasma treatment of the substrate 200 is carried out to remove the photoresist layer 208. Oxygen plasma, for example, is used in the plasma treatment.

Since the aforementioned oxygen plasma treatment is conducted after the inert gas treatment 204 has produced a densified protective layer 206, the dielectric layer 202 is protected against any attacks by oxygen plasma. Hence, deterioration of electrical properties of the dielectric layer 202 due to plasma attack is prevented.

Furthermore, the inert gas plasma required by the inert gas plasma treatment 204 can be produced by the PECVD station used for forming the dielectric layer 202. In other words, the inert gas plasma treatment 204 is compatible with conventional manufacturing step and there is no need to purchase new equipment.

Table 2 lists out some test parameters showing the difference in properties for a dielectric constant film with or without a nitrogen plasma treatment.

TABLE 2
Test results of a low dielectric constant film with
or without nitrogen plasma treatment

| | Post- | | | Oxygen Ashing |
|---|---|---|---|---|
| Surface | Deposition | Oxygen Ashing | Nitrogen | After Nitrogen |
| Treatment | (untreated) | Treatment | Treatment | Treatment |
| Dielectric | 2.72 | 2.94 | 2.72 | 2.75 |
| Constant | | | | |
| Breakdown | 6.1 | 5.14 | 5.96 | 5.86 |
| Voltage | | | | |
| (MV/cm) | | | | |
| Thickness loss | 0 | 164 | <10 | <40 |
| (Å) | | | | |

Before any treatment of the low dielectric constant film (organosilicate) treatment, the film has a dielectric constant of about 2.72, a breakdown voltage of about 6.1 MV/cm and a film loss of 0 Å (as shown in column 2 of Table 2). After an oxygen ashing treatment, the dielectric constant increases to about 2.94, the breakdown voltage drops to about 5.14 MV/cm and the film loss is about 164 Å (as shown in column 3 of Table 2). Therefore, electrical properties of the low dielectric constant deteriorate after oxygen ashing treatment.

After a nitrogen plasma treatment, the dielectric constant remains at about 2.72, the breakdown voltage drops to about 5.96 MV/cm and the film loss is less than 10 Å (as shown in column 4 of Table 1). Hence, the nitrogen plasma treatment has a minor effect on the electrical properties of the low dielectric constant film.

If the oxygen ashing treatment is conducted after the nitrogen plasma treatment, the dielectric constant increases slightly to about 2.75, the breakdown voltage drops to about 5.86 MV/cm and the film loss is less than 40 Å (as shown in column 5 of Table 2). Thus, the oxygen ashing treatment affects the properties of the low dielectric constant film only lightly. In other words, the inert gas plasma treatment is able to protect the low dielectric constant film against subsequent oxygen ashing treatment.

In summary, the advantages of this invention includes:

1. A densified layer, which can serve as a protective layer, is formed over a low dielectric constant film after an inert gas plasma treatment. The inert gas plasma treatment has a minor effect on the intrinsic properties of the dielectric film.

2. The protective layer formed by inert gas plasma treatment is able to protect the low dielectric constant film against plasma attacks such as hydrogen plasma for removing metallic oxide material or oxygen plasma for removing photoresist material.

3. Inert gas plasma used in inert gas plasma treatment can be produced inside a plasma-enhanced chemical vapor deposition station. In other words, there is no need to purchase additional equipment just to implement the process according to this invention.

In the embodiments of this invention, plasma-enhanced chemical vapor deposition (PECVD) is used to form the low dielectric constant film. However, PECVD is not the only means of forming a low dielectric constant film. Hence, this invention does not limit the fabrication of a low dielectric constant film to PECVD. In fact, other processes such as spin-on-coating may also be used.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of densifying a superficial layer of a low dielectric constant film, comprising:
providing a substrate having a low dielectric constant material layer thereon; and
performing an inert gas plasma treatment of the substrate so that a superficial layer of the low dielectric constant material layer is densified into a protective layer.

2. The method of claim 1, wherein gas used in the inert gas plasma treatment is selected from a group consisting of nitrogen, helium and argon.

3. The method of claim 1, wherein an operating pressure used in the inert gas plasma treatment is between about 0.1 and 10 torrs.

4. The method of claim 1, wherein an operating power used in the inert gas plasma treatment is between about 0.5 and 10 W/cm².

5. The method of claim 1, wherein an operating temperature used in the inert gas plasma treatment is between about 250° C. and 450° C.

6. A method of forming a metallic interconnect structure, comprising:
providing a substrate;
forming a low dielectric constant material layer over the substrate;
forming a dual damascene structure in the low dielectric constant material layer;
performing an inert gas plasma treatment of the substrate so that a superficial layer of the low dielectric constant material layer is densified into a protective layer; and
performing a hydrogen plasma treatment of the dual damascene structure to remove metallic oxide material on a surface of the dual damascene structure.

7. The method of claim 6, wherein the inert gas plasma treatment and formation of the low dielectric constant material are carried out in a single reaction chamber.

8. The method of claim 6, wherein gas used in the inert gas plasma treatment is selected from a group consisting of nitrogen, helium and argon.

9. The method of claim 6, wherein an operating pressure used in the inert gas plasma treatment is between about 0.1 and 10 torrs.

10. The method of claim 6, wherein an operating power used in the inert gas plasma treatment is between about 0.5 and 10 W/cm².

11. The method of claim 6, wherein an operating temperature used in the inert gas plasma treatment is between about 250° C. and 450° C.

12. The method of claim 6, wherein the protective layer has a thickness between about b 10 Å and 300 Å.

13. A method of forming a low dielectric constant film pattern, comprising:
providing a substrate;
forming a low dielectric constant material layer over the substrate;
performing an inert gas plasma treatment of the substrate so that a superficial layer of the low dielectric constant material layer is densified into a protective layer;
forming a patterned photoresist layer over the low dielectric constant material layer;
etching the low dielectric constant material layer while using the photoresist layer as a mask to form an opening; and
performing a plasma treatment on the substrate to remove the photoresist layer.

14. The method of claim 13, wherein the low dielectric constant material layer is formed by plasma-enhanced chemical vapor deposition and the inert gas plasma treatment is carried out inside the same plasma-enhanced chemical vapor deposition chamber.

15. The method of claim 13, wherein a gas used in the inert gas plasma treatment is selected from a group consisting of nitrogen, helium and argon.

16. The method of claim 13, wherein an operating pressure used in the inert gas plasma treatment is between about 0.1 and 10 torrs.

17. The method of claim 13, wherein an operating power used in the inert gas plasma treatment is between about 0.5 and 10 W/cm².

18. The method of claim 13, wherein an operating temperature used in the inert gas plasma treatment is between about 250° C. and 450° C.

19. The method of claim 13, wherein the protective layer has a thickness between about 10 Å and 300 Å.
